(19) United States
(12) Patent Application Publication
(10) Pub. No.: US 2026/0279874 A1
(43) Pub. Date: Sep. 17, 2026

(54) APPARATUS AND METHOD FOR MANUFACTURING SECONDARY BATTERY

(71) Applicant: SK ON CO., LTD., Seoul (KR)

(72) Inventors: Eun Soo CHO, Daejeon (KR); Jae Hyun JEON, Daejeon (KR); Jun Hui JEONG, Daejeon (KR)

(21) Appl. No.: 19/530,366

(22) Filed: Feb. 5, 2026

(30) Foreign Application Priority Data
Feb. 5, 2025 (KR) 10-2025-0014652
Dec. 3, 2025 (KR) 10-2025-0189677

(51) Int. Cl. H01M 10/04; H01M 4/04; H01M 50/609

(52) U.S. Cl. CPC H01M 10/0404; H01M 4/0445; H01M 50/609

(57) ABSTRACT

An apparatus for manufacturing a secondary battery according to various embodiments of the present disclosure may include: an electrolyte injection unit coupled to an injection port of a preliminary battery cell including a first electrode and a second electrode to inject an electrolyte; a power unit connected to the first electrode and the second electrode and configured to apply a voltage while the electrolyte is injected into the preliminary battery cell; a pressure control unit configured to regulate a pressure within the preliminary battery cell while the electrolyte is injected into the preliminary battery cell; a heating unit disposed on one side of the preliminary battery cell to heat the preliminary battery cell; and a control unit configured to control the application of voltage by the power unit.

### CROSS-REFERENCE TO RELATED APPLICATIONS

This patent application claims the priority and benefits of Korean patent applications No. 10-2025-0014652, filed on Feb. 5, 2025, and No. 10-2025-0189677, filed on Dec. 3, 2025, the disclosure of which is incorporated herein by reference in its entirety.

### BACKGROUND OF THE INVENTION

### 1. Field of the Invention

The present disclosure relates to an apparatus and a method for manufacturing a secondary battery.

### 2. Description of the Related Art

Various types of secondary batteries are used as energy sources in electric vehicles or electronic devices. In the secondary batteries, a jelly-roll-type electrode assembly, in which an anode, a cathode, and a separator are wound together, is used, or alternatively, an electrode assembly fabricated by stacking an anode, a cathode, and a separator in an appropriate order may be used.

This electrode assembly is accommodated in a battery case and connected to an anode terminal and a cathode terminal, and the case is then sealed after being filled with an electrolyte.

### SUMMARY OF THE INVENTION

An object of the present disclosure is to provide an apparatus and a method for manufacturing a secondary battery capable of improving the wettability of an electrolyte during the process of manufacturing a secondary battery.

Secondary batteries manufactured by the apparatus for manufacturing a secondary battery according to various embodiments of the present disclosure may be widely applied in green technology fields, such as electric vehicles, battery charging stations, as well as solar power generation, wind power generation, and the like, which use the batteries. Secondary batteries manufactured by the apparatus for manufacturing a secondary battery of the present disclosure may be used in eco-friendly electric vehicles, hybrid vehicles, and the like, which are aimed at mitigating climate change by reducing air pollution and greenhouse gas emissions.

An apparatus for manufacturing a secondary battery according to various embodiments of the present disclosure may include: an electrolyte injection unit coupled to an injection port of a preliminary battery cell including a first electrode and a second electrode to inject an electrolyte; a power unit connected to the first electrode and the second electrode and configured to apply a voltage while the electrolyte is injected into the preliminary battery cell; a pressure control unit configured to regulate a pressure within the preliminary battery cell while the electrolyte is injected into the preliminary battery cell; a heating unit disposed on one side of the preliminary battery cell to heat the preliminary battery cell; and a control unit configured to control the application of voltage by the power unit.

In one embodiment, the control unit may terminate voltage application based on the pressure within the preliminary battery cell controlled by the pressure control unit.

In one embodiment, the pressure control unit may decrease or increase the pressure within the preliminary battery cell for a preset impregnation time, and the control unit may terminate voltage application based on whether the impregnation time has elapsed.

In one embodiment, the control unit may terminate voltage application by the power unit based on the charging current density of the preliminary battery cell charged by the power unit.

In one embodiment, the control unit may terminate voltage application by the power unit when the charging current density decreases to within a range of 0.001 C to 0.1 C.

In one embodiment, the control unit may control voltage application by the power unit so that a state of charge (SOC) of the preliminary battery cell is less than 1% or a terminal voltage (cell voltage) of the preliminary battery cell is less than 2.5 V.

In one embodiment, the power unit may apply a voltage after liquid injection into the preliminary battery cell is completed.

In one embodiment, the power unit may be coupled to a lower end portion of the preliminary battery cell and electrically connected to the first electrode and the second electrode.

In one embodiment, the power unit may include a seating part on which a lower surface of the preliminary battery cell is seated, and a support part disposed around the seating part so as to surround at least a portion of a side surface of the preliminary battery cell.

In one embodiment, the power unit may include a pair of probes that contact the first electrode and the second electrode to apply a voltage.

In one embodiment, a sensing member that is spaced apart from the pair of probes and connected to the preliminary battery cell may be disposed on the seating part.

In one embodiment, the heating unit may include a heating body disposed to surround at least a portion of a side surface of the preliminary battery cell.

In one embodiment, the heating body may include a first heating body that covers a portion of the side surface of the preliminary battery cell and a second heating body that covers the remaining portion of the side surface of the preliminary battery cell, and the first heating body and the second heating body may be coupled to each other while surrounding the side surface of the preliminary battery cell.

In one embodiment, the heating unit may heat the preliminary battery cell so that the temperature thereof is increased at a constant rate after electrolyte injection by the electrolyte injection unit starts.

In one embodiment, the liquid injection unit may include a hopper that contains the electrolyte and an injection line that connects the hopper and the liquid injection port, and the pressure control unit may be connected to the hopper and may control the pressure within the preliminary battery cell through the injection line.

In one embodiment, the control unit may control the voltage applied to the preliminary battery cell within a range of greater than 0 V and 1 V or less.

A method for manufacturing a secondary battery according to various embodiments of the present disclosure may include: a preparation step of electrically connecting a preliminary battery cell including a first electrode and a second electrode to a power unit; an injection step of injecting an electrolyte into the preliminary battery cell by an injection unit; and a voltage application step of applying a voltage to the first electrode and the second electrode of the preliminary battery cell by a power unit while the electrolyte is injected into the preliminary battery cell, wherein the liquid injection step and the voltage application step are performed while the preliminary battery cell is heated by a heating unit.

In one embodiment, the method may include a pressure control step of increasing or decreasing a pressure within the preliminary battery cell for a preset impregnation time by a pressure control unit after the electrolyte is injected into the preliminary battery cell, wherein the voltage application step may be terminated depending on whether the impregnation time has elapsed.

In one embodiment, the voltage application step may be terminated when a charging current density of the preliminary battery cell charged by the power unit decreases to within a preset range.

In one embodiment, in the voltage application step, the voltage application by the power unit may be controlled by a control unit so that a state of charge of the preliminary battery cell is less than 1% or a terminal voltage (cell voltage) of the preliminary battery cell is less than 2.5 V.

The apparatus for manufacturing a secondary battery according to various embodiments of the present disclosure may improve the wettability of an electrolyte in an electrode assembly.

### BRIEF DESCRIPTION OF THE DRAWINGS

The above and other objects, features and advantages of the present disclosure will be more clearly understood from the following detailed description taken in conjunction with the accompanying drawings, in which:

FIG. 1 is a schematic view illustrating an apparatus for manufacturing a secondary battery according to an embodiment of the present disclosure;

FIG. 2 is a schematic view illustrating a power unit of the apparatus for manufacturing a secondary battery according to an embodiment of the present disclosure;

FIG. 3 is a graph illustrating temporal changes in pressure (vacuum/pressurization), voltage, and temperature applied to a preliminary battery cell through the apparatus for manufacturing a secondary battery according to an embodiment of the present disclosure;

FIG. 4 is a block diagram illustrating the configuration relationship of the apparatus for manufacturing a secondary battery according to an embodiment of the present disclosure; and

FIG. 5 is a flowchart describing a method for manufacturing a secondary battery according to an embodiment of the present disclosure.

### DETAILED DESCRIPTION OF THE INVENTION

The embodiments of the present disclosure are provided to more fully describe the present disclosure to those skilled in the art to which the present invention pertains. The following embodiments may be modified in various forms, and the scope of the present disclosure is not limited to these embodiments.

Hereinafter, some embodiments of the present disclosure will be described through exemplary drawings for the convenience of description. When assigning reference numerals to components of the respective drawings, it should be noted that the same components will be denoted by the same reference numerals, even if they appear in different drawings.

The terms or words used in this specification and the claims should not be construed as being limited to their conventional or lexical meanings, and instead, in accordance with the principle that an inventor may define the concepts of terms or words in the most appropriate manner to describe the invention, they should be interpreted based on the meanings and concepts that meet the technical spirit of the present disclosure.

The terms used herein are provided to describe specific embodiments and are not intended to limit the present disclosure. As used herein, the singular form may include the plural form unless the context clearly dictates otherwise.

In addition, when used to describe and define the present disclosure, terms such as “comprise,” “include,” “consist of,” and “have” should be interpreted in a non-exclusive manner. Unless explicitly stated otherwise, these terms should be construed to imply that the presence of the corresponding component, and not to exclude but rather include other components.

In addition, in describing components of the embodiment of the present disclosure, the terms such as first, second, A, B, (a), (b), and the like may be used. These terms are used to distinguish the component from other components and do not impose any limitations on their nature, sequence or order, etc.

It will be understood that when a component is described as being “connected” or “coupled” to another component, the component may be directly connected or coupled to the other component, but it may be “connected” or “coupled” to the other component with another component possibly interposed.

Space-related terms such as “beneath,” “below,” “lower,” “above,” and “upper” may be used to aid in the understanding of the relationship between an element or feature and another illustrated in the drawings. These space-related terms are provided to aid in the understanding of the present disclosure in various processing or usage states and are not intended to impose any limitations on the present disclosure. For example, if an element or feature in the drawing is turned upside down, the element or feature described as “beneath” or “below” becomes “above” or “upper.” Accordingly, the term “beneath” is a relative concept that may encompass “upper” as well as “below” depending on orientation.

The embodiments described in this specification and the configurations illustrated in the drawings merely represent the most preferred embodiments of the present disclosure but do not encompass all aspects of the technical spirit of the present disclosure. Thus, it should be understood that various modifications and equivalents may be implemented at the time of filing the present application. In addition, the publicly known functions and configurations that are deemed unnecessary for clarifying the essence of the present invention will not be described.

Hereinafter, an apparatus and a method for manufacturing a cylindrical secondary battery according to various embodiments of the present disclosure will be described in detail with reference to the accompanying drawings.

The secondary battery described in the present disclosure may be any type of conventional battery cell capable of converting the chemical energy of materials stored in the battery into electrical energy, and capable of supporting multiple charge and discharge cycles. For example, the secondary battery may refer to any one of a lithium cobalt battery, a lithium high-nickel battery, a lithium iron phosphate battery, a lithium-ion battery, a lithium polymer battery, a lithium-sulfur battery, a nickel hydrogen battery, a nickel cadmium battery, a sodium battery, or an all-solid-state battery. For example, the secondary battery may refer to, but is not limited to, a lithium-ion secondary battery.

A preliminary battery cell 10 described in the present disclosure may, without limitation, refer to an unfinished battery cell. For example, the preliminary battery cell 10 may refer to a state in which an electrode assembly is accommodated in a case 11 and an electrolyte has not been injected into or impregnated into the electrode assembly.

The apparatus and method for manufacturing a secondary battery according to the present disclosure may provide an apparatus and a method for performing an electrolyte injection process and an electrolyte impregnation process for the preliminary battery cell 10.

The secondary battery in the present disclosure may be a product manufactured using the apparatus and method for manufacturing a secondary battery according to an embodiment of the present disclosure from the preliminary battery cell 10.

In one embodiment of the present disclosure, the preliminary battery cell 10 may include an electrode assembly accommodated in the case 11.

The electrode assembly may include a first electrode, a second electrode, and a separator. The electrode assembly may be provided, without limitation, in a stacked form, in which the first electrode, the second electrode, and the separator are stacked.

The first electrode and the second electrode may each include an electrode coating layer and a current collector.

The first electrode may be either a cathode or an anode. If the first electrode is a cathode, the second electrode may be an anode, and if the first electrode is an anode, the second electrode may be a cathode.

For example, the first electrode may be a cathode. In one embodiment, the first electrode may include a first current collector in the form of a metal foil and a first electrode coating layer on which a first electrode active material is coated.

For example, the first current collector may be a cathode current collector and may include any one of stainless steel, nickel (Ni), aluminum (Al), titanium (Ti), copper (Cu), and an alloy thereof. The cathode current collector may be provided in various forms, such as a film, a sheet, or a foil. The cathode current collector may have a thickness, for example, but not limited to, 10 to 50 μm. For example, the first current collector may include aluminum.

In one embodiment, the first electrode coating layer may be an electrically conductive coating and may include a cathode active material. Examples of the cathode active material may include lithium nickel manganese cobalt oxide (NMC), lithium manganese oxide (LMO), lithium iron phosphate (LFP), lithium cobalt oxide (LCO), lithium titanate (LTO), or a chalcogenide (LiTiS2) compound, but are not limited thereto, and any cathode active material known to those skilled in the art may be used.

In one embodiment, the first current collector may include a first coating part on which a first electrode coating layer is formed and a first uncoated part on which no first electrode active material is coated.

The second electrode may be either a cathode or an anode. For example, the second electrode may be an anode. In one embodiment, the second electrode may include a second current collector in the form of a metal foil and a second electrode coating layer on which a second electrode active material is coated.

For example, non-limiting examples of the second current collector may include a copper foil, nickel foil, stainless steel foil, titanium foil, nickel foam, copper foam, or a polymer substrate coated with a conductive metal. The anode current collector may have a thickness of, but is not limited to, 10 to 50 μm. For example, the second current collector may include copper.

In one embodiment, the second electrode coating layer may be an electrically conductive coating and may include an anode active material. For example, the anode active material may be a material capable of adsorbing and desorbing lithium ions. For example, as the anode active material, carbon-based materials such as crystalline carbon, amorphous carbon, carbon composites, or carbon fibers, etc. ; lithium metal; a lithium alloy; a silicon (Si)-containing material or a tin (Sn)-containing material, and the like may be used.

The amorphous carbon may include hard carbon, soft carbon, coke, mesocarbon microbead (MCMB), mesophase pitch-based carbon fiber (MPCF) or the like.

The crystalline carbon may include graphite-based carbon such as natural graphite, artificial graphite, graphitized coke, graphitized MCMB, graphitized MPCF or the like.

The lithium metal may include pure lithium metal or lithium metal having a protective layer formed thereon for suppressing dendrite growth, etc. In one embodiment, a lithium metal-containing layer deposited or coated on the anode current collector may be used as the anode active material layer. In one embodiment, a lithium thin-film layer may also be used as the anode active material layer.

Elements contained in the lithium alloy may include aluminum, zinc, bismuth, cadmium, antimony, silicon, lead, tin, gallium or indium, etc.

The silicon-containing material may provide further increased capacity characteristics. The silicon-containing material may include Si, SiOₓ (0<x<2), a metal-doped SiOₓ (0<x<2), a silicon-carbon composite, etc. The metal may include lithium and/or magnesium, and the metal-doped SiOₓ (0<x<2) may include a metal silicate. However, this is merely exemplary, and the anode active material that can be included in the second electrode coating layer is not limited thereto, and any anode active material known to those skilled in the art may be used.

In one embodiment, the second current collector may include a second coating part on which a second electrode coating layer is formed, and a second uncoated part on which no second electrode coating layer is formed.

The separator may be interposed between the first electrode and the second electrode to prevent the first electrode and the second electrode from being electrically connected to each other and causing a short circuit. The separator may be configured to allow the flow of ions between the first electrode and the second electrode. In some embodiments, the separator may have a thickness of 10 μm to 20 μm, but the present disclosure is not limited thereto. For example, the separator may include an electrically insulating material.

For example, the separator may include a polymeric material. The separator may include a porous polymer film or a porous non-woven fabric. The porous polymer film may include a polyolefin polymer such as an ethylene polymer, a propylene polymer, an ethylene/butene copolymer, an ethylene/hexene copolymer, or an ethylene/methacrylate copolymer. The porous non-woven fabric may include glass fibers having a high melting point, polyethylene terephthalate fibers and the like. The separator may also include a ceramic material. For example, the separator may improve heat resistance by coating inorganic particles on the polymer film or dispersing inorganic particles within the polymer film.

The separator may have a single-layer or multilayer structure including the above-described polymer film and/or non-woven fabric.

The electrode assembly may include the above-described first electrode, separator, and second electrode stacked. For example, the cathode, the anode, and the separator may be repeatedly disposed to form the electrode assembly. For example, the first electrode, the separator, and the second electrode may be formed in a stacking type, a stack-folding type structure, or a zigzag folding type structure, and may also be wound in a jelly roll shape.

In one embodiment, the first uncoated part and the second uncoated part may be exposed on one side and the other side of the electrode assembly, respectively. For example, the first uncoated part and the second uncoated part may be disposed on one side of the electrode assembly so as to be spaced apart from each other. For example, the first uncoated part and the second uncoated part may be exposed to opposite axial ends of the electrode assembly. The first uncoated part and the second uncoated part exposed to the outside of the electrode assembly may define electrode tabs.

For example, each electrode tab (a cathode tab and an anode tab) may protrude from the electrode assembly and extend to one side of the case 11. The electrode tabs may be fused to the one side of the case 11 and connected to electrode leads (a cathode lead and an anode lead) that extend or are exposed to the outside of the case 11.

For example, as the case 11 of the secondary battery, a pouch-shaped case 11, a square case 11, a cylindrical case 11, a coin-shaped case 11, and the like may be used, but is not limited thereto.

The electrode assembly described above may be accommodated in the case 11 together with an electrolyte. The apparatus for manufacturing a secondary battery of the present disclosure may inject an electrolyte while the electrode assembly is accommodated in the case 11. According to an embodiment, a non-aqueous electrolyte may be used as the electrolyte.

The non-aqueous electrolyte may include a lithium salt of an electrolyte and an organic solvent. The lithium salt is represented by, for example, Li⁺X⁻, and as an anion (X⁻) of the lithium salt, F⁻, Cl⁻, Br⁻, I⁻, NO₃⁻, N(CN)₂⁻, BF₄⁻, ClO₄⁻, PF₆⁻, (CF₃)₂PF₄⁻, (CF₃)₃PF₃⁻, (CF₃)₄PF₂⁻, (CF₃)₅PF⁻, (CF₃)₆P⁻, CF₃SO₃⁻, CF₃CF₂SO₃⁻, (CF₃SO₂)₂N⁻, (FSO₂)₂N⁻, CF₃CF₂(CF₃)₂CO⁻, (CF₃SO₂)₂CH⁻, (SF₅)₃C⁻, (CF₃SO₂)₃C⁻, CF₃(CF₂)₇SO₃⁻, CF₃CO₂⁻, CH₃CO₂⁻, SCN⁻ and (CF₃CF₂SO₂)₂N⁻, the like may be exemplified.

The organic solvent may include an organic compound which has sufficient solubility for the lithium salt and the additive, and is electrochemically stable without exhibiting reactivity in the battery. For example, the organic solvent may include at least one of a carbonate solvent, an ester solvent, an ether solvent, a ketone solvent, an alcohol solvent and an aprotic solvent. As the organic solvent, for example, propylene carbonate (PC), ethylene carbonate (EC), butylene carbonate, diethyl carbonate (DEC), dimethyl carbonate (DMC), ethyl methyl carbonate (EMC), methyl propyl carbonate, ethylpropyl carbonate, dipropyl carbonate, vinylene carbonate, methyl acetate (MA), ethyl acetate (EA), n-propylacetate (n-PA), 1,1-dimethylethyl acetate (DMEA), methyl propionate (MP), ethyl propionate (EP), fluoroethyl acetate (FEA), difluoroethyl acetate (DFEA), trifluoroethyl acetate (TFEA), dibutyl ether, tetraethylene glycol dimethyl ether (TEGDME), diethylene glycol dimethyl ether (DEGDME), tetrahydrofuran (THF), 2-methyltetrahydrofuran, ethyl alcohol, isopropyl alcohol, dimethyl sulfoxide, acetonitrile, dimethoxyethane, diethoxyethane, sulfolane, γ-butyrolactone, propylene sulfite, and the like may be used. These may be used alone or in combination of two or more thereof.

The non-aqueous electrolyte may further include an additive. The additive may include, for example, a cyclic carbonate compound, a fluorine-substituted carbonate compound, a sultone compound, a cyclic sulfate compound, a cyclic sulfite compound, a phosphate compound, a borate compound and the like.

The cyclic carbonate compound may include vinylene carbonate (VC), vinyl ethylene carbonate (VEC), etc.

The fluorine-substituted carbonate compound may include fluoroethylene carbonate (FEC), etc.

The sultone compound may include 1,3-propane sultone, 1,3-propene sultone, 1,4-butane sultone, etc.

The cyclic sulfate compound may include 1,2-ethylene sulfate, 1,2-propylene sulfate, etc.

The cyclic sulfite compound may include ethylene sulfite, butylene sulfite, etc.

The phosphate compound may include lithium difluoro bis(oxalato) phosphate, lithium difluorophosphate, etc.

The borate compound may include lithium bis(oxalate) borate, etc.

The preliminary battery cell 10 to which the apparatus for manufacturing a secondary battery according to various embodiments of the present disclosure is applied may refer to an unfinished battery cell for manufacturing a secondary battery, including the case 11 in which an electrode assembly is accommodated therein and in which an injection port is formed on one side while accommodating the electrode assembly.

In the present disclosure, the preliminary battery cell 10 may refer to a battery cell that is not yet fully completed. For example, the preliminary battery cell 10 may refer to the preliminary battery cell 10 including an electrode assembly and the case 11 that accommodates the electrode assembly therein, but in which an electrolyte is not injected into the case 11.

The secondary battery manufactured by the apparatus for manufacturing a secondary battery of the present disclosure may refer to a can-shaped secondary battery. For example, the secondary battery may include a cylindrical or prismatic secondary battery.

For example, the case 11 of the preliminary battery cell 10 may be formed in a cylindrical shape, but is not limited thereto.

The apparatus for manufacturing a secondary battery of the present disclosure may be implemented as a single apparatus. The manufacturing apparatus may be implemented in a form in which individual devices responsible for specific functions are integrated into a single apparatus.

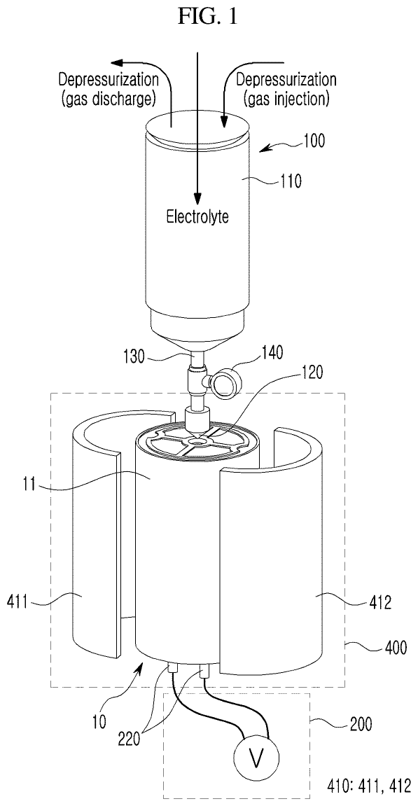

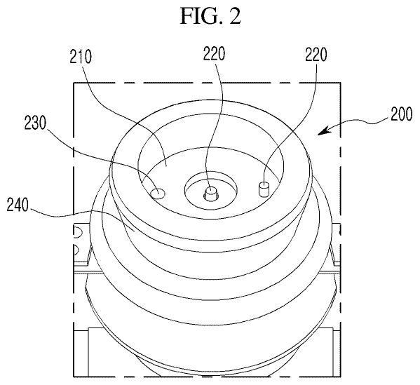

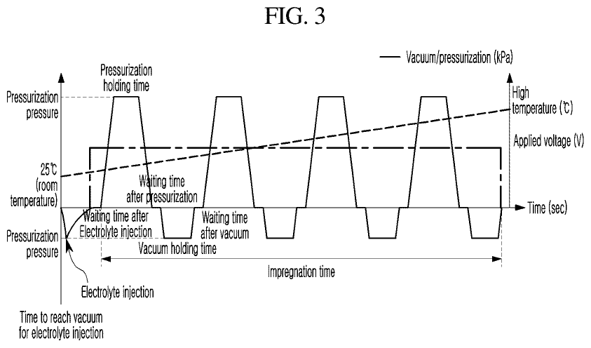

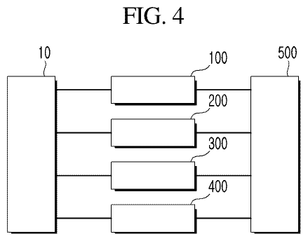

FIG. 1 is a schematic view illustrating the apparatus for manufacturing a secondary battery according to an embodiment of the present disclosure, FIG. 2 is a schematic view illustrating a power unit of the apparatus for manufacturing a secondary battery according to an embodiment of the present disclosure, FIG. 3 is a graph illustrating temporal changes in pressure (vacuum/pressurization), voltage, and temperature applied to the preliminary battery cell through the apparatus for manufacturing a secondary battery according to an embodiment of the present disclosure, and FIG. 4 is a block diagram illustrating the configuration relationship of the apparatus for manufacturing a secondary battery according to an embodiment of the present disclosure.

Hereinafter, with reference to FIGS. 1 to 4, the apparatus for manufacturing a secondary battery of the present disclosure and the process of manufacturing a secondary battery by applying it to the preliminary battery cell 10 will be described in detail.

Referring to FIGS. 1 to 4, the apparatus for manufacturing a secondary battery according to various embodiments of the present disclosure may include an injection unit 100 coupled to an injection port of the preliminary battery cell 10 including a first electrode and a second electrode to inject an electrolyte, a power unit 200 connected to the first electrode and the second electrode to apply a voltage while the electrolyte is injected into the preliminary battery cell 10, a pressure control unit 300 configured to regulate the pressure inside the preliminary battery cell 10 while the electrolyte is injected into the preliminary battery cell 10, a heating unit 400 disposed on one side of the preliminary battery cell 10 and configured to heat the preliminary battery cell 10, and a control unit 500 configured to control the application of a voltage to the first electrode and the second electrode by the power unit 200.

The injection unit 100 of the apparatus for manufacturing a secondary battery may inject an electrolyte into the preliminary battery cell 10 with an electrode assembly accommodated therein. In one embodiment, the injection unit 100 may include a hopper 110 that contains an electrolyte to be injected into the case 11, a nozzle 120 coupled to the injection port of the case 11, and an injection line 130 that connects the hopper 110 and the nozzle 120 and provides an injection path of the electrolyte.

In one embodiment, the hopper 110 may be configured to contain a predetermined amount of electrolyte to be injected into the case 11 of the preliminary battery cell 10. The hopper 110 may be configured to store the predetermined amount of electrolyte to be injected into the case 11, and may be configured to accommodate the predetermined amount of electrolyte in advance. The injection line 130 may be connected to a lower end portion of the hopper 110 for transporting the electrolyte to the injection nozzle 120. A flow rate detection unit 140 may be disposed in the injection line 130 to detect the flow of the electrolyte. For example, the hopper 110 may further include a temperature control device or a stirring device to detect the remaining amount of the electrolyte within the hopper or to ensure process stability.

The nozzle 120 may form a portion of a flow path through which the electrolyte flows and may be coupled to the injection port opened at an upper end of the case 11. The nozzle 120 may be coupled to the injection port to be sealed against the injection port. For example, the nozzle 120 may include at least a portion formed of a material capable of elastic deformation to enhance sealing against the injection port. For example, at least a partial section of a lower end portion of the nozzle 120 may be configured to have a narrow tapered shape with a diameter that decreases as it extends downward. However, the nozzle 120 in the apparatus for manufacturing a secondary battery according to the present disclosure is not limited thereto, and any shape known at the time of application may be applied as long as the nozzle 120 can be sealed against the injection port of the case 11. For example, the nozzle 120 may be coupled to the injection port by moving relative to the case 11.

The apparatus for manufacturing a secondary battery may include the flow rate detection unit 140 disposed on the injection line 130 between the hopper 110 and the nozzle 120. The flow rate detection unit 140 may detect the flow rate in real time while the electrolyte is being injected from the hopper 110 and transmit the detected flow rate data to the control unit 500. For example, the flow rate detection unit 140 may include a communication module capable of transmitting and receiving electrical signals to and from the control unit 500.

For example, the flow rate detection unit 140 may be composed of a mass flow controller (MFC) or a flow sensor similar thereto, and may include a flow rate detection sensor and a transmission circuit to convert real-time flow rate information into a digital signal. For example, the control unit 500 may perform a determination regarding the process of manufacturing a secondary battery (e.g., determining injection completion, waiting for stabilization, controlling valve opening and closing timing, etc.) based on the data received from the flow rate detection unit 140, thereby improving the uniformity and accuracy of the electrolyte injection.

In addition, the flow rate detection unit 140 may compensate for flow rate fluctuations due to changes in the viscosity or temperature of the electrolyte, or detect abnormal pressure or bubble inclusions within an electrolyte supply line to identify process abnormalities at an early stage.

The power unit 200 of the apparatus for manufacturing a secondary battery may apply a current and/or voltage to the preliminary battery cell 10. The power unit 200 may improve the wettability of the electrolyte by applying the current or voltage to the first electrode and the second electrode of the preliminary battery cell 10.

For example, the power unit 200 may be electrically connected to the first electrode and the second electrode of the preliminary battery cell 10, and may apply a current or voltage to the first electrode and the second electrode. For example, the power unit 200 may be coupled to a lower end portion of the preliminary battery cell 10 and may be electrically connected to the first electrode and the second electrode. For example, the power unit 200 may be connected to the first electrode and the second electrode while the electrolyte is injected into the preliminary battery cell 10, and may apply a voltage.

In one embodiment, the power unit 200 may include a seating part 210 on which a lower surface of the preliminary battery cell 10 is seated, and a support part 240 disposed around the seating part 210 to surround at least a portion of a side surface of the preliminary battery cell 10.

The seating part 210 may be provided in a shape corresponding to a lower surface of the case 11 of the preliminary battery cell 10. For example, the seating part 210 may be provided in a circular shape, but is not limited thereto. For example, a terminal of the first electrode may be disposed on one side of the lower surface of the case 11 of the preliminary battery cell 10. In addition, a terminal of the second electrode may be disposed on another side of the lower surface of the case 11 so as to be insulated from the terminal of the first electrode.

The power unit 200 may include a pair of probes 220 that contact the first electrode and the second electrode to apply a voltage. One of the pair of probes 220 may be disposed so that it contacts the terminal of the first electrode of the preliminary battery cell 10, and the other probe contacts the terminal of the second electrode. In this case, the seating part 210 may be formed of an insulating material, so that the pair of probes 220 may be electrically insulated from each other. For example, the pair of probes 220 may have an interchangeable structure made of a metal alloy, a conductive elastomer, or the like.

However, while the present disclosure exemplarily describes the first terminal and the second terminal of the preliminary battery cell 10 as being respectively disposed on the lower surface of the case 11, but is not limited thereto. In addition, it should be understood that the pair of probes 220 of the power unit 200 may be disposed at any location that can be electrically connected to the first terminal and the second terminal of the preliminary battery cell 10, respectively.

Meanwhile, a sensing member 230 spaced apart from the pair of probes 220 and connected to the preliminary battery cell 10 may be disposed on the seating part 210. The sensing member 230 may include a measurement unit for precisely detecting a terminal voltage (cell voltage), internal resistance (ESR), current response (dI/dt), and the like of the preliminary battery cell 10 during application of power. For example, the sensing member 230 may include a communication module capable of transmitting/receiving an electrical signal regarding the sensing result, thereby providing the sensing result to the control unit 500 in real time. For example, the sensing member 230 may be disposed on one side of the seating part 210 and may be in contact with the lower surface of the case 11. For example, the sensing member 230 may be in contact with the electrode terminal of the preliminary battery cell 10, but is not limited thereto, and may be in contact with a region other than the electrode terminal. In addition, the sensing member 230 may be used as feedback for controlling the heating unit 400 by detecting the surface temperature of the preliminary battery cell 10.

The support part 240 may be disposed to extend upward along a circumference of the seating part 210. The support part 240 may support a partial section of the lower portion of the case 11. For example, the support part 240 may be provided in a cylindrical shape to correspond to a lower portion of the cylindrical case 11, but is not limited thereto. For example, the support part 240 may be formed integrally with the seating part 210. For example, the support part 240 may be formed of an insulating material and be electrically insulated from the case 11 of the preliminary battery cell 10.

In one embodiment, the power unit 200 of the apparatus for manufacturing a secondary battery may further include a heat shielding layer to prevent heat generated by the heating unit 400 or heat emitted from the case 11 from being transmitted to an electric circuit. For example, the heat shielding layer may include a ceramic sheet or an air gap, but is not limited thereto.

In one embodiment, the power unit 200 may apply a current or voltage to the preliminary battery cell 10 in various ways for various purposes. For example, as described below, the power unit 200 may apply a current or voltage to the preliminary battery cell 10 in order to charge the first electrode and the second electrode during an impregnation process in which an electrolyte is injected into the preliminary battery cell 10 to impregnate the first electrode and the second electrode. However, it is not limited thereto, and the power unit 200 may also apply a current or voltage to the preliminary battery cell 10 in order to charge and discharge the preliminary battery cell 10 for the purpose of activating the preliminary battery cell 10 after the impregnation process is completed.

In one embodiment, the power unit 200 may apply a voltage after the injection of the electrolyte into the preliminary battery cell 10 is completed. For example, the power unit 200 may apply a low voltage (e.g., greater than 0 V and 1 V or less) between the electrodes immediately after the injection of the electrolyte to improve the rate at which the electrolyte penetrates into the micropores of an electrode active material layer. In one embodiment, the power unit 200 may apply a voltage of 0.1 V to 0.5 V to the preliminary battery cell 10 for a preset impregnation time, and at this time, the charging current density of the preliminary battery cell 10 may be maintained in a range of 0.001 C to 0.05 C. By applying the low voltage as described above, an electric double layer is formed at the interface between the electrode and the electrolyte, and the interfacial tension is changed, so that the wettability of the electrolyte may be improved.

In one embodiment, the power unit 200 may receive control signals from the control unit 500, such as current profiles, application times, and applied voltages, and may operate in constant current (CC), constant voltage (CV), pulse, or cyclic application modes based thereon.

For example, the power unit 200 may monitor the status of the pressure control unit 300 and the heating unit 400 and may also receive an interlock signal to apply a voltage only when internal pressure and temperature conditions are within a set range.

For example, the power unit 200 may be controlled to apply a low voltage only during the vacuum-pressurization cycle after electrolyte injection, or to allow application only after the temperature of the preliminary battery cell 10 is increased to 25 to 40° C. by the heating unit 400.

In addition, the power unit 200 may continuously transmit current density, terminal voltage, dV/dt, and dI/dt through real-time communication with the control unit 500, and the control unit 500 may use this feedback to terminate voltage application when the charging current density decreases to within a range of 0.001 C to 0.1 C, or limit the applied voltage so that the state of charge of the preliminary battery cell 10 is less than 1% or the terminal voltage is less than 2.5 V. Accordingly, the apparatus for manufacturing a secondary battery of the present disclosure may stabilize the impregnation process while preventing side reactions such as overpotential generation in the electrode, electrolyte decomposition, and abnormal SEI growth.

The apparatus for manufacturing a secondary battery of the present disclosure may include the pressure control unit 300. The pressure control unit 300 may increase or decrease the pressure within the case 11 of the preliminary battery cell 10. During the electrolyte injection process, the pressure control unit 300 may decrease the pressure within the case 11 to a vacuum state below atmospheric pressure or increase the pressure above atmospheric pressure, thereby enhancing the wettability of the electrolyte in the electrode assembly.

For example, the pressure control unit 300 may be connected to the hopper 110 or may be branched and disposed on the injection line 130. For example, the pressure control unit 300 may be connected to the hopper 110 and control a pressure within the preliminary battery cell 10 through the injection line 130.

The pressure control unit 300 may include a vacuum pump or vacuum generator capable of decreasing the pressure inside the preliminary battery cell 10 to below atmospheric pressure, a gas supply source (e.g., an inert gas such as nitrogen) capable of increasing the pressure above atmospheric pressure, and a pressure control valve system that controls the flow of these gases.

In addition, the pressure control unit 300 may further include a pressure sensor that measures the pressure inside the preliminary battery cell 10 in real time and may provide feedback to the control unit 500. For example, the pressure sensor may be disposed within the hopper 110, the injection line 130, and/or the case 11. For example, the apparatus for manufacturing a secondary battery may detect abnormal pressure drops, backflow, and bubble inclusions by synchronously analyzing the pressure response detected by the pressure sensor and the flow rate change detected by the flow rate detection unit 140 through the control unit 500.

The pressure control unit 300 may ensure smooth electrolyte injection through the injection unit 100 by reducing the pressure inside the case 11 of the preliminary battery cell 10 to a vacuum state (below atmospheric pressure) before injection of the electrolyte.

For example, the pressure control unit 300 may effectively remove air and other gases remaining within the pores of the electrode assembly, thereby securing space for the electrolyte to penetrate. Furthermore, the pressure control unit 300 may promote impregnation by decreasing the internal pressure of the case 11, thereby creating a pressure differential that strongly draws the electrolyte into the micropores.

After electrolyte injection, the pressure control unit 300 may repeatedly perform a depressurization period below atmospheric pressure (e.g., 10 to 30 kPa absolute pressure) and a pressurization period above atmospheric pressure (e.g., 150 to 250 kPa absolute pressure) for a preset impregnation time.

For example, the pressure control unit 300 may promote electrolyte penetration into the micropores of the electrode by pressurizing the interior of the case 11 above atmospheric pressure for a preset period of time while the electrolyte is injected into the case 11 of the preliminary battery cell 10.

Thereafter, the pressure control unit 300 may depressurize the interior of the case 11 back to a vacuum state for a preset period of time to remove any remaining pores within the electrode.

Meanwhile, when controlling the pressure within the preliminary battery cell 10 through the pressure control unit 300, the control unit 500 may provide a waiting period between pressurization and depressurization to maintain the internal pressure at atmospheric pressure for a preset period of time. Accordingly, the pressure control unit 300 may prevent electrolyte scattering due to rapid changes in the pressure.

In the apparatus for manufacturing a secondary battery of the present disclosure, the depressurization-pressurization cycle performed by the pressure control unit 300 may be repeated multiple times during the impregnation time, thereby maximizing the impregnation effect.

In one embodiment, the depressurization/pressurization operations of the pressure control unit 300 may be controlled by the control unit 500 and may be controlled to operate in conjunction with the power unit 200 and the heating unit 400.

The apparatus for manufacturing a secondary battery may include the heating unit 400 disposed on one side of the preliminary battery cell 10 to heat the preliminary battery cell 10. The heating unit 400 may heat the preliminary battery cell 10 so that the temperature thereof is increased at a constant rate after the injection by the injection unit 100 starts. The start and end times of the heating unit 400 may be controlled by the control unit 500.

In one embodiment, the heating unit 400 may include a heat source for transferring heat to the preliminary battery cell 10. For example, the heat source may be disposed on the surface of the heating unit 400 and be in contact with the outer surface of the preliminary battery cell 10 to directly heat the case 11 of the preliminary battery cell 10. For example, the heat source may be disposed inside the heating unit 400 to heat the outer surface of the case 11 by radiating heat. However, the heat source of the heating unit 400 is not limited thereto, and any heat source known at the time of application may be used as long as it can heat the preliminary battery cell 10 to increase the temperature thereof.

In one embodiment, the heating unit 400 may include a heating body 410 that transfers heat to the preliminary battery cell 10 using a heat source.

The heating body 410 may be disposed in a form capable of efficiently transferring heat to the preliminary battery cell 10. In one embodiment, the heating body 410 may be disposed to surround at least a portion of a side surface of the preliminary battery cell 10. For example, the heating body 410 may be disposed to cover the entire area of the side surface of the preliminary battery cell 10. In one embodiment, the heating body 410 may heat the side surface of the preliminary battery cell 10 by dividing it into two or more regions in a vertical direction. For example, the heating body 410 may uniformly transfer heat through the widest area of the preliminary battery cell 10 and effectively distribute the temperature throughout the electrode assembly.

For example, the heating body 410 may include a first heating body 411 that covers a portion of the side surface of the preliminary battery cell 10 and a second heating body 412 that covers the remaining portion of the side surface of the preliminary battery cell 10. For example, the first heating body 411 and the second heating body 412 may be coupled to each other while surrounding the side surface of the preliminary battery cell 10. For example, the first heating body 411 and the second heating body 412 may be configured to be openable using a hinge, latch, sliding jaw, or the like, and when coupled, may secure a uniform heating surface along the circumference of the case 11 of the preliminary battery cell 10. In addition, the heating body 410 may facilitate loading and unloading of the preliminary battery cell 10 and may allow mounting of the preliminary battery cell 10 by flexibly corresponding to various sizes and shapes.

In the present disclosure, the heating unit 400 may increase the temperature of the preliminary battery cell 10 to lower the viscosity of the electrolyte injected into the case 11, thereby reducing the flow resistance of the electrolyte and facilitating its penetration into the micropores within the electrode assembly, and thereby increasing the impregnation rate.

In one embodiment, the heating unit 400 may increase the temperature of the preliminary battery cell 10 after the injection by the injection unit 100 has started. Alternatively, in one embodiment, the heating unit 400 may start heating the case 11 of the preliminary battery cell 10 in advance before the injection by the injection unit 100 starts.

In one embodiment, the heating unit 400 may be controlled so that the external surface temperature of the preliminary battery cell 10 falls in a range of 25° C. to 40° C. For example, the preliminary battery cell 10 may have a temperature of approximately 20° C. to 30° C. at the start of injection and may be gradually increased to 40° C. until the preset impregnation time has elapsed. However, the temperature range is exemplary and may vary depending on the viscosity of the electrolyte and the characteristics of the electrode assembly.

The control unit 500 may control the injection unit 100, the power unit 200, the pressure control unit 300, and the heating unit 400.

In one embodiment, the control unit 500 may control operations of the injection unit 100, the power unit 200, the pressure control unit 300, and the heating unit 400 in an integrated and coordinated manner, thereby maximizing wettability of electrolyte within electrode assembly.

For example, the control unit 500 may perform pressure control (vacuum/pressurization cycles) by the pressure control unit 300 while increasing a temperature (reducing electrolyte viscosity) by the heating unit 400 and applying a voltage (inducing an electrocapillary force) by the power unit 200, thereby providing an optimal environment that reduces the physical, thermal, and electrical resistance of electrolyte impregnation and increasing wettability.

In one embodiment, when the case 11 of the preliminary battery cell 10 is seated on the seating part 210 of the power unit 200, the control unit 500 may initiate the electrolyte injection and impregnation process. For example, the control unit 500 may determine whether the preliminary battery cell 10 is seated by checking whether the sensing member 230, disposed on the seating part 210, is in contact with the case 11 of the preliminary battery cell 10.

In one embodiment, once the preliminary battery cell 10 is seated on the seating part 210 and is ready for electrolyte injection, the control unit 500 may control the injection unit 100 to inject the electrolyte.

For example, the control unit 500 may control the injection unit 100 in a closed-loop manner. For example, the control unit 500 may adjust the electrolyte injection rate and injection time through the injection line 130 based on real-time flow rate data received from the flow rate detection unit 140. For example, the control unit 500 may control valve opening or pump operation to maintain a target flow rate range when injection starts, and automatically terminate injection when a set cumulative injection amount or time condition is satisfied.

In one embodiment, the control unit 500 may control the injection unit 100 to perform injection only after the temperature of the preliminary battery cell 10 reaches a target range through heating of the heating unit 400, thereby maintaining the viscosity and fluidity of the electrolyte in an optimized state.

In one embodiment, the control unit 500 may control the heating unit 400 so that the temperature of the preliminary battery cell 10 is maintained within a range suitable for electrolyte impregnation (e.g., 25 to 40° C.). For example, the control unit 500 may control the operation of the heating unit 400 using a temperature signal detected from the sensing member 230 of the power unit 200. For example, the control unit 500 may stepwise control the operation of the heating unit 400 until the sensed temperature value reaches a set target temperature (e.g., 25 to 40° C.).

The control unit 500 may maintain the temperature of the preliminary battery cell 10 for a predetermined period of time after electrolyte injection to reduce the viscosity of the electrolyte and promote its penetration into the electrodes.

In one embodiment, the control unit 500 may control the voltage application of the power unit 200 to occur only when the heating temperature of the preliminary battery cell 10 by the heating unit 400 reaches a target range.

For example, the control unit 500 may independently control the first heating body 411 and the second heating body 412 of the heating unit 400 to maintain a uniform temperature distribution across upper and lower portions of the preliminary battery cell 10. Alternatively, the control unit 500 may divide the heating unit 400 into a plurality of sections in the vertical direction and independently control each section.

In one embodiment, the control unit 500 may control the power unit 200 to maintain the voltage applied to the preliminary battery cell 10 within a range of greater than 0 V and 1 V or less. For example, the control unit 500 may detect the terminal voltage and current in real time through the sensing member 230 and precisely maintain the voltage within the range of greater than 0 V and 1 V or less through feedback control.

For example, the control unit 500 may prevent electrode damage or overpotential by limiting the potential increase rate at the beginning of voltage application. For example, the control unit 500 may allow voltage application only when the temperature of the preliminary battery cell 10 reaches a set range (e.g., 25 to 40° C.) due to heating by the heating unit 400. For example, the control unit 500 may control the power unit 200 to operate in conjunction with a pressure condition so that voltage is applied only during the depressurization or vacuum holding time of the preliminary battery cell 10 by the pressure control unit 300. For example, the control unit 500 may immediately stop the voltage application if the voltage exceeds the upper limit (1 V) or if the temperature or pressure conditions are not satisfied. Thereby, the control unit 500 may prevent side reactions and secure process stability while realizing uniform impregnation of the electrolyte.

In one embodiment, the control unit 500 may calculate a charging current density (J=I/A) of the preliminary battery cell 10 using a feedback signal of the current response (dI/dt) or current amount (I) received from the sensing member 230 of the power unit 200. For example, the control unit 500 may terminate the voltage application by the power unit 200 based on the charging current density of the preliminary battery cell 10 charged by the power unit 200.

For example, the control unit 500 may terminate the voltage application when the calculated charging current density decreases below a preset threshold, thereby preventing overpotential or electrolyte decomposition and determining a stable termination point for impregnation. For example, the preset threshold may be set to a range of charging current densities, and the control unit 500 may terminate the voltage application by the power unit 200 when the charging current density decreases to within the range of 0.001 C to 0.1 C. For example, the control unit 500 may prevent unnecessary overpotential by terminating the voltage application when the charging current density decreases to within the range of 0.001 C to 0.01 C.

In one embodiment, the control unit 500 may control the magnitude and duration of the voltage applied between the first electrode and the second electrode of the preliminary battery cell 10 by the power unit 200, monitor a state of charge (SOC) and the cell voltage of the preliminary battery cell 10 in real time, and control the voltage application so that these values are maintained within a set safety limit range.

In one embodiment, the control unit 500 may calculate the state of charge of the preliminary battery cell 10 using the current and cell voltage data received from the sensing member 230 of the power unit 200. For example, the control unit 500 may calculate the SOC using the charge amount obtained by current integration and the rated capacity of the preliminary battery cell 10. Alternatively, for example, the control unit 500 may correct the SOC by referencing the terminal voltage and previously stored open circuit voltage-SOC correlation data. The control unit 500 may use the calculated state of charge of the preliminary battery cell 10 as a control parameter for voltage application.

In one embodiment, the control unit 500 may control the voltage application by the power unit 200 so that the state of charge of the preliminary battery cell 10 is less than 1% or the terminal voltage of the preliminary battery cell 10 is less than 2.5 V.

For example, the control unit 500 may prevent excessive electrode activation due to lithium ion migration within the electrolyte during the impregnation step by limiting the voltage applied so that the SOC is less than 1%.

For example, the control unit 500 may control the applied voltage of the power unit 200 so that the terminal voltage of the preliminary battery cell 10 is less than 2.5 V, thereby preventing side reactions such as electrolysis of the electrolyte or abnormal SEI layer formation.

For example, the control unit 500 may monitor changes in the terminal voltage in real time during voltage application, and when the voltage increase rate exceeds a set value or the voltage exceeds an upper limit (e.g., 2.5 V), the control unit 500 may control the output voltage of the power unit 200 to immediately decrease or temporarily suspend the voltage application.

In addition, when the SOC calculation result reaches a target value (e.g., 1%), the control unit 500 may determine the corresponding time point as a voltage application termination signal and terminate the voltage application.

Through the above-described control, the control unit 500 may suppress excessive formation of an electric double layer at the interface between the electrode and the electrolyte by finely controlling internal reactions of the preliminary battery cell 10, and may induce the electrolyte to be uniformly impregnated into the electrode under stable electrical conditions. Therefore, the control unit 500 according to the present disclosure may improve the reliability and reproducibility of the electrolyte impregnation process by performing a feedback-based voltage control function based on the electrical state variables (SOC, terminal voltage, etc.) of the preliminary battery cell 10 as well as by simple voltage application sequence control.

The control unit 500 may control the pressure control unit 300 to cause the internal pressure of the preliminary battery cell 10 to vary according to a preset pressure profile. The pressure profile may be defined as a target pressure curve over time and may be divided into a depressurization phase, a maintenance phase, a pressurization phase, and a return phase. For example, the control unit 500 may control the pressure control unit 300 to reduce the internal pressure to a vacuum state lower than atmospheric pressure before electrolyte injection, maintain the pressure for a predetermined period of time, and then repeatedly switch between a pressurized state and a depressurized state after electrolyte injection.

In one embodiment, the control unit 500 may terminate voltage application based on the internal pressure of the preliminary battery cell 10 controlled by the pressure control unit 300.

In one embodiment, the pressure control unit 300 may depressurize or pressurize the internal pressure of the preliminary battery cell 10 for a preset impregnation time, and the control unit 500 may terminate voltage application depending on whether the impregnation time has elapsed. For example, the preset impregnation time may be 5 to 60 minutes, but is not limited thereto. For example, the control unit 500 may determine the end time of voltage application, pressure control, or heating based on the elapsed impregnation time.

To maximize electrolyte impregnation efficiency, the control unit 500 may coordinate low voltage application with depressurization-pressurization cycles of the pressure control unit 300, and may use completion of preset pressure-control steps as key criterion for terminating voltage application. This pressure-based synchronous control may effectively prevent side reactions that compromise cell stability, such as electrolyte decomposition and abnormal SEI layer growth due to unnecessary low voltage application, by suspending electrical application upon completion of physical impregnation.

The control unit 500 may collect data from the pressure sensor in real time to precisely control the opening and closing of the valve and the pump, thereby preventing rapid pressure fluctuations and electrolyte splashing. For example, the control unit 500 may control the pressure control unit 300 to perform multiple repetitions of the depressurization-pressurization cycle, and may control interlock conditions in conjunction with the power unit 200 to ensure that voltage is applied only during a corresponding period. Therefore, both the electrolyte impregnation efficiency and process stability within the preliminary battery cell 10 may be simultaneously secured.

In one embodiment, the apparatus for manufacturing a secondary battery according to the present disclosure may operate in the following sequence.

First, the preliminary battery cell 10 may be seated on the power unit 200, and the heating unit 400 may be installed around the preliminary battery cell 10. The apparatus for manufacturing a secondary battery may gradually increase the temperature of the preliminary battery cell 10 to approximately 25° C. by the heating unit 400. Thereafter, the apparatus for manufacturing a secondary battery may perform electrolyte injection while maintaining the interior of the preliminary battery cell 10 in a vacuum state by the pressure control unit 300. Upon completion of the electrolyte injection, the internal pressure of the preliminary battery cell 10 may be increased to 150 kPa to 250 kPa, and then internal gas may be removed to depressurize the preliminary battery cell 10. The depressurization and pressurization cycles may be repeated multiple times within a preset impregnation time. For example, the apparatus for manufacturing a secondary battery may apply a voltage in a range of greater than 0 V and 1 V or less to the preliminary battery cell 10 by the power unit 200 while repeatedly performing the depressurization and pressurization cycles. Meanwhile, the apparatus for manufacturing a secondary battery may terminate the voltage application when the charging current density decreases to within the range of 0.001 C to 0.01 C, for example. At this time, the internal pressure control and voltage application processes for the preliminary battery cell 10 may be performed while the preliminary battery cell 10 is gradually heated by the heating unit 400.

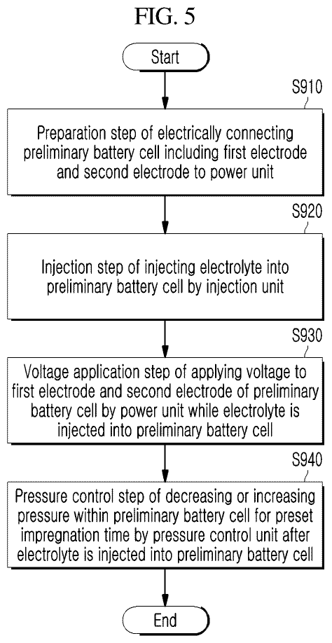

FIG. 5 is a flowchart describing a method for manufacturing a secondary battery according to an embodiment of the present disclosure.

Referring to FIG. 5, the method for manufacturing a secondary battery of the present disclosure may include a preparation step S910 of electrically connecting the preliminary battery cell 10 including a first electrode and a second electrode to the power unit 200, an injection step S920 of injecting an electrolyte into the preliminary battery cell 10 by the injection unit 100, and a voltage application step S930 of applying a voltage to the first electrode and the second electrode of the preliminary battery cell 10 by the power unit 200 while the electrolyte is injected into the preliminary battery cell 10, wherein the injection step and the voltage application step may be performed while the preliminary battery cell 10 is heated by the heating unit 400.

In the preparation step S910, the preliminary battery cell 10 may be seated on the seating part 210 of the power unit 200. When the preliminary battery cell 10 is seated on the seating part 210, the control unit 500 may determine whether the preliminary battery cell 10 is seated through the sensing member 230. When the preliminary battery cell 10 is seated on the power unit 200, the control unit 500 may start the injection step. When the nozzle 120 is coupled to the injection port of the preliminary battery cell 10, the electrolyte may be injected into the interior of the case 11 through the injection port.

In one embodiment, the control unit 500 may depressurize the interior of the case 11 to a vacuum state by the pressure control unit 300 before the electrolyte is injected. Therefore, the actual electrolyte injection may be performed while the interior of the case 11 is depressurized to below atmospheric pressure.

Once the injection is completed, the control unit 500 may release the vacuum state and gradually pressurize the interior of the case 11 to atmospheric pressure. For example, in the method for manufacturing a secondary battery, the control unit 500 may control the pressure control unit 300 and the power unit 200 to perform the voltage application step S930 and/or the pressure control step S940 after maintaining a preset waiting time at atmospheric pressure.

Meanwhile, the control unit 500 may determine whether the injection is completed through the flow rate detection unit 140. Once the injection is completed, the pressure control unit 300 may pressurize the interior of the case 11 to ensure sufficient electrolyte impregnation into the electrodes.

Once the injection of the preliminary battery cell 10 is completed, the control unit 500 may control the power unit 200 to apply a voltage to the first electrode and the second electrode of the preliminary battery cell 10 during the voltage application step. For example, after the electrolyte is injected by the injection unit 100, the control unit 500 may monitor the status of the pressure control unit 300 and the heating unit 400 and initiate the application of a low voltage (e.g., greater than 0 V and 1 V or less).

In one embodiment, in the voltage application step S930, the control unit 500 may maintain the voltage applied to the first electrode and the second electrode at a preset voltage. In one embodiment, when the charging current density of the preliminary battery cell 10 charged by the power unit 200 decreases to within a preset range, the voltage application step S930 may be terminated. In one embodiment, in the voltage application step S930, the voltage application by the power unit 200 may be controlled by the control unit 500 so that the state of charge of the preliminary battery cell 10 is less than 1% or the terminal voltage (cell voltage) of the preliminary battery cell 10 is less than 2.5 V.

Meanwhile, the secondary battery manufacturing method of the present disclosure may include a pressure control step S940 of increasing or decreasing the pressure within the preliminary battery cell 10 for a preset impregnation time by the pressure control unit 300 after the electrolyte is injected into the preliminary battery cell 10. At this time, the above-described voltage application step may be terminated depending on whether the impregnation time has elapsed. In one embodiment, the pressure control step S940 may be performed simultaneously with or in parallel with the above-described voltage application step.

In one embodiment, the control unit 500 may control the heating unit 400 to heat the preliminary battery cell 10 so that the temperature thereof is increased at a constant rate. For example, the heating unit 400 may start heating after the injection has started, but is not limited thereto. The heating unit 400 may also start heating the preliminary battery cell 10 before the injection has started. For example, when the preliminary battery cell 10 is seated on the power unit 200, the heating unit 400 may start heating the preliminary battery cell 10.

Meanwhile, in the method for manufacturing a secondary battery of the present disclosure, the pressure control step S940 and/or the voltage application step S930 described above may be performed for a preset impregnation time, and may be performed while the preliminary battery cell 10 is heated by the heating unit 400.

The apparatus for manufacturing a secondary battery according to the various embodiments of the present disclosure described above may improve the wettability of the electrolyte in the electrode assembly by integrated control of the depressurization/pressurization, heating, and low-voltage application conditions.

The secondary battery manufacturing apparatus of the present disclosure may maintain the electrolyte's inflow force (capillary force), fluidity (viscosity), and interfacial activity (electric double layer) conditions in an optimized state from the beginning of the process by simultaneously applying depressurization and pressurization, heating, and low voltage application. This combined control may rapidly establish a point at which the electrolyte uniformly penetrates deep into the micropores of the electrode assembly, and may maintain the electrode-electrolyte interface in a stable state throughout the impregnation process.

In addition, the apparatus for manufacturing a secondary battery may control termination of voltage application using current density, SOC, and terminal voltage to prevent excessive electrochemical reactions after sufficient impregnation has been achieved, thereby suppressing side reactions such as unnecessary electrolyte decomposition, excessive SEI growth, and local current concentration.

Therefore, the apparatus and method for manufacturing a secondary battery of the present disclosure may simultaneously improve the electrolyte penetration rate and penetration uniformity, while also improving initial charge/discharge stability and variations in cell characteristics, ultimately enhancing the quality, durability, and yield of the secondary battery.

In the above, although the embodiments of the present disclosure have been described with all components coupled in one or operating in combination, the present disclosure is not necessarily limited to such embodiments. Within the scope of the purpose of the present disclosure, all components may be selectively coupled in one or more forms and operate accordingly. Unless otherwise defined, all terms including technical or scientific terms have the same meanings as commonly understood by those skilled in the art to which the present disclosure pertains. Commonly used terms, such as those defined in dictionaries, should be interpreted in accordance with their contextual meanings in the relevant technical field, and unless explicitly defined in the present disclosure, shall not be interpreted in an idealized or unduly formal sense.

The above description is merely illustrative of the technical spirit of the present disclosure, and it will be appreciated by those skilled in the art to which the present disclosure pertains that various modifications and variations can be made without departing from the essential characteristics of the present disclosure. Therefore, the embodiments disclosed herein are intended to describe, not to limit, the technical spirit of the present disclosure, and the scope of the technical spirit is not limited to these embodiments. The scope of protection of the present disclosure shall be defined by the following claims, and all technical spirits that fall within the equivalent scope shall be construed as being included within the scope of the present disclosure.

What is claimed is:

1. An apparatus for manufacturing a secondary battery comprising:
an electrolyte injection unit coupled to an injection port of a preliminary battery cell comprising a first electrode and a second electrode to inject an electrolyte;
a power unit connected to the first electrode and the second electrode and configured to apply a voltage while the electrolyte is injected into the preliminary battery cell;
a pressure control unit configured to regulate a pressure within the preliminary battery cell while the electrolyte is injected into the preliminary battery cell;
a heating unit disposed on one side of the preliminary battery cell to heat the preliminary battery cell; and
a control unit configured to control the application of voltage by the power unit.

2. The apparatus for manufacturing a secondary battery according to claim 1, wherein the control unit terminates voltage application based on the pressure within the preliminary battery cell controlled by the pressure control unit.

3. The apparatus for manufacturing a secondary battery according to claim 2, wherein the pressure control unit decreases or increases the pressure within the preliminary battery cell for a preset impregnation time, and
the control unit terminates voltage application based on whether the impregnation time has elapsed.

4. The apparatus for manufacturing a secondary battery according to claim 1, wherein the control unit terminates voltage application by the power unit based on the charging current density of the preliminary battery cell charged by the power unit.

5. The apparatus for manufacturing a secondary battery according to claim 4, wherein the control unit terminates voltage application by the power unit when the charging current density decreases to within a range of 0.001 C to 0.1 C.

6. The apparatus for manufacturing a secondary battery according to claim 1, wherein the control unit controls voltage application by the power unit so that a state of charge (SOC) of the preliminary battery cell is less than 1% or a terminal voltage (cell voltage) of the preliminary battery cell is less than 2.5 V.

7. The apparatus for manufacturing a secondary battery according to claim 3, wherein the power unit applies a voltage after liquid injection into the preliminary battery cell is completed.

8. The apparatus for manufacturing a secondary battery according to claim 1, wherein the power unit is coupled to a lower end portion of the preliminary battery cell and electrically connected to the first electrode and the second electrode.

9. The apparatus for manufacturing a secondary battery according to claim 8, wherein the power unit comprises a seating part on which a lower surface of the preliminary battery cell is seated, and a support part disposed around the seating part so as to surround at least a portion of a side surface of the preliminary battery cell.

10. The apparatus for manufacturing a secondary battery according to claim 9, wherein the power unit comprises a pair of probes that contact the first electrode and the second electrode to apply a voltage.

11. The apparatus for manufacturing a secondary battery according to claim 9, wherein a sensing member that is spaced apart from the pair of probes and connected to the preliminary battery cell is disposed on the seating part.

12. The apparatus for manufacturing a secondary battery according to claim 1, wherein the heating unit includes a heating body disposed to surround at least a portion of a side surface of the preliminary battery cell.

13. The apparatus for manufacturing a secondary battery according to claim 12, wherein the heating body comprises a first heating body that covers a portion of the side surface of the preliminary battery cell and a second heating body that covers the remaining portion of the side surface of the preliminary battery cell, and
wherein the first heating body and the second heating body are coupled to each other while surrounding the side surface of the preliminary battery cell.

14. The apparatus for manufacturing a secondary battery according to claim 1, wherein the heating unit heats the preliminary battery cell so that the temperature thereof is increased at a constant rate after electrolyte injection by the electrolyte injection unit starts.

15. The apparatus for manufacturing a secondary battery according to claim 1, wherein the liquid injection unit comprises a hopper that contains the electrolyte and an injection line that connects the hopper and the liquid injection port, and
wherein the pressure control unit is connected to the hopper and controls the pressure within the preliminary battery cell through the injection line.

16. The apparatus for manufacturing a secondary battery according to claim 1, wherein the control unit controls the voltage applied to the preliminary battery cell within a range of greater than 0 V and 1 V or less.

17. A method for manufacturing a secondary battery, comprising:
a preparation step of electrically connecting a preliminary battery cell comprising a first electrode and a second electrode to a power unit;
an injection step of injecting an electrolyte into the preliminary battery cell by an injection unit; and
a voltage application step of applying a voltage to the first electrode and the second electrode of the preliminary battery cell by a power unit while the electrolyte is injected into the preliminary battery cell,
wherein the liquid injection step and the voltage application step are performed while the preliminary battery cell is heated by a heating unit.

18. The method for manufacturing a secondary battery according to claim 17, comprising a pressure control step of increasing or decreasing a pressure within the preliminary battery cell for a preset impregnation time by a pressure control unit after the electrolyte is injected into the preliminary battery cell,
wherein the voltage application step is terminated depending on whether the impregnation time has elapsed.

19. The method for manufacturing a secondary battery according to claim 18, wherein the voltage application step is terminated when a charging current density of the preliminary battery cell charged by the power unit decreases to within a preset range.

20. The method for manufacturing a secondary battery according to claim 18, wherein in the voltage application step, the voltage application by the power unit is controlled by a control unit so that a state of charge of the preliminary battery cell is less than 1% or a terminal voltage (cell voltage) of the preliminary battery cell is less than 2.5 V.
